(19) United States
(12) Patent Application Publication
(10) Pub. No.: US 2008/0157320 A1
(43) Pub. Date: Jul. 3, 2008

(54) Laterally Interconnected IC Packages and Methods

(76) Inventors: Ray D. Harrison, Garland, TX (US); Jianbai Zhu, Plano, TX (US); Jeffrey J. Wolfe, Sachse, TX (US); Frank Stepniak, Dallas, TX (US)

Correspondence Address: TEXAS INSTRUMENTS INCORPORATED, P O BOX 655474, M/S 3999, DALLAS, TX, 75265, US

(21) Appl. No.: 11/617,906

(22) Filed: Dec. 29, 2006

(51) Int. Cl. H01L 23/48; H01L 21/58

(52) U.S. Cl. 257/686; 438/107; 257/E23.01; 257/E21.505

(57) ABSTRACT

Semiconductor devices and methods for their assembly are described in which IC packages may be combined in novel configurations. A multi-package semiconductor device system and associated methods for its construction include a plurality of packaged semiconductor devices, each provided with at least one lateral electrical contact. The plurality of packaged semiconductor devices so provided are fixed in a coplanar configuration and have the adjacent lateral contacts coupled for operation in concert.

### TECHNICAL FIELD

The invention relates to electronic semiconductor devices and manufacturing. More particularly, the invention relates to microelectronic semiconductor devices and their packages and to methods and systems for implementing assemblies having lateral interconnections among IC packages.

### BACKGROUND OF THE INVENTION

Semiconductor device assemblies are subject to many competing design goals. It is very often desirable to minimize the size of electronic apparatus. At the same time, the demand for increased features results in an increase in the number of components on a given device. Efforts are continuously underway to design and manufacture devices with reduced area, but attempts to increase density while reducing area must inevitably reach a practical limit.

In lateral multi-device layouts, semiconductor devices are placed on a planar substrate such as a PCB or PWB. Typically, electrical connections are made between each device and the substrate by coupling the bond pads of each device to corresponding bond pads on the substrate. Coupling devices to one another is also completed through interconnections among the bond pads of the substrate, which link up traces encompassed within the layers of the substrate. One notable disadvantage of this type of arrangement is the area required on the substrate. Area is occupied by the devices themselves, and additional area is occupied by the interconnections and by the traces contained within the substrate.

As efforts are made to maximize the use of substrate area, vertical stacking of components becomes increasingly attractive. Stacked Package-on-Package (PoP) semiconductor device assemblies containing two or more packaged semiconductor devices stacked vertically typically include a first device attached to a substrate such as a PCB or PWB. Bond pads are disposed around some or all of the periphery of the first device. Bond wires electrically connect the bond pads of the first device to corresponding bond pads located on the substrate. A second device is affixed to the exposed surface of the first device, sometimes using a spacer between the first and second device. Bond pads similarly disposed on the top surface of the second device are then electrically connected to bond pads on the substrate. One or more additional devices may also in turn be stacked in a similar manner to form a multi-layer PoP assembly containing two, three, or more stacked packages operably coupled to one another through the substrate interface. Typically, encapsulant is applied in order to cover the stacked semiconductor packages, the wire bonds, and at least a portion of the substrate. Variations in stacking methods and structures exist in terms of materials and process steps, for example, ball bonding may be used instead of or in addition to wirebonding, but the overall scheme described is representative of the general practice known in the arts for using a PCB or PWB interface for coupling multiple wirebond or surface mount semiconductor devices within a single PoP assembly. Overall reduction of the footprint of a common PoP assembly is achieved primarily due to the reduction in area occupied by the stacked devices themselves. Routing area in the PCB/PWB generally does not benefit as much and may in some cases actually increase in order to accommodate interconnections among the stacked devices. Other standard package or PoP interconnects are performed in a vertical manner, either from a single package to PWB/PCB, or top package to primary package to PWB/PCB.

There is a need in the art for multi-package semiconductor assemblies with improved performance and reduced footprints. Such improved assemblies, and methods for their manufacture, would be useful and advantageous in the arts. The present invention is directed to overcoming, or at least reducing the effects of, one or more of the problems mentioned above.

### SUMMARY OF THE INVENTION

In carrying out the principles of the present invention, in accordance with preferred embodiments thereof, the invention provides multi-package semiconductor device assemblies having direct lateral electrical connections among adjacent packages for direct communication, reducing their reliance on a common substrate interface.

According to one aspect of the invention, in a preferred embodiment, a multi-package semiconductor device system includes first and second packaged semiconductor devices each having a lateral electrical contact. The first and second packaged semiconductor devices are fixed in a coplanar configuration and have the adjacent lateral contacts coupled for operation in concert.

According to another aspect of the invention, three or more packaged semiconductor devices each have at least one lateral electrical contact and are fixed in a coplanar configuration. Connections among the lateral electrical contacts associate the devices for operation with at least some electrical signals passing among them without reliance on vertical communication with an underlying substrate.

According to yet another aspect of the invention, a multi-package semiconductor device system includes a substrate with a vertical electrical interface underlying at least one of the packaged semiconductor devices. At least one packaged semiconductor device of the system is operably coupled to at least one additional packaged semiconductor device using a plurality of vertical connections in a package-on-package system configuration.

The invention has numerous advantages including but not limited to providing methods and devices offering one or more of the following; smaller package footprints, higher pin count packages for given footprints, faster data throughput, and reduced costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view illustrating an example of a preferred embodiment of the invention;

FIG. 2 is a close-up cutaway partial side view illustrating an example of preferred embodiments of the invention;

FIG. 3 is a close-up cutaway partial side view illustrating an example of alternative preferred embodiments of the invention;

FIG. 4 is a cutaway side view illustrating an example of a PoP assembly implementing a preferred embodiment of the invention; and

FIG. 5 is a cutaway side view illustrating another example of a PoP assembly implementing a preferred embodiment of the invention.

References in the detailed description correspond to like references in the various Figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides improvements in multi-package semiconductor device assemblies. Laterally interconnected multi-IC configurations facilitate direct communication of electronic signals among adjacent semiconductor devices with decreased reliance on a board interface.

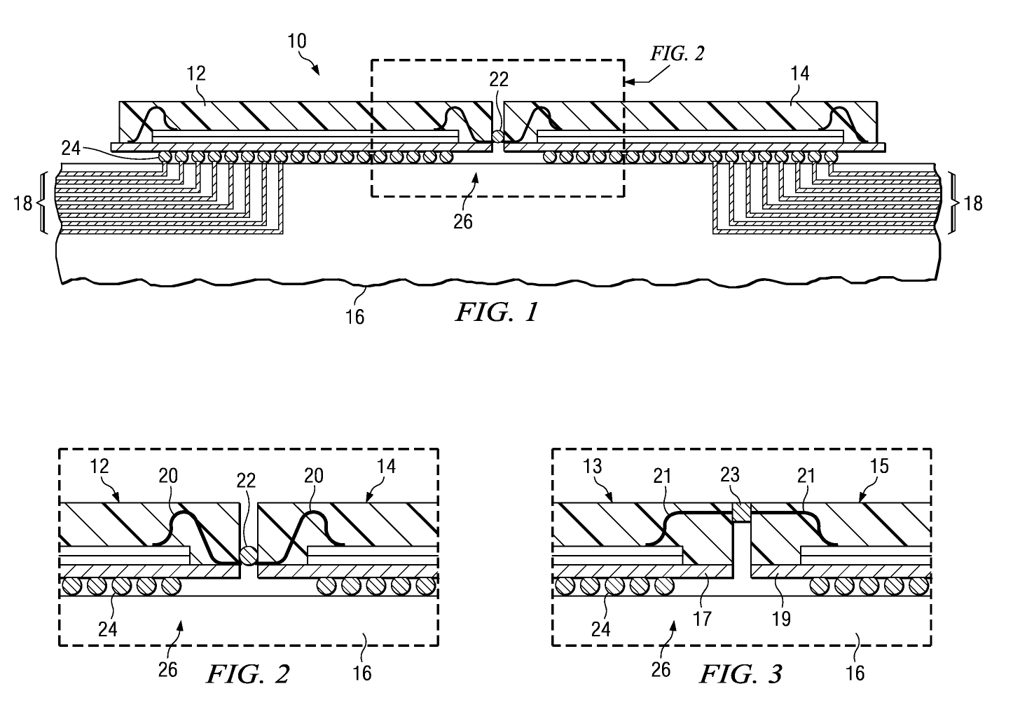

Now referring primarily to FIG. 1, an example of preferred embodiments of the invention are shown. A multi-package semiconductor device system 10 has a first packaged semiconductor device 12 and a second packaged semiconductor device 14. The first and second devices 12, 14, are adjacent to one another in a coplanar configuration, preferably affixed on a substrate 16, in this case a PCB, although other suitable substrates may be used, such as a PWB, or in the context of a PoP system, another packaged device or coplanar grouping of packaged devices. The substrate 16 typically includes subsurface metallic traces 18 within. The first device 12, and the second device 14, each have at least one lateral electrical contact 20 suitable for completing an operable electrical connection. As also shown in the close-up view of FIG. 2, preferably, the lateral contacts 20 of two similarly configured coplanar devices, e.g., first and second devices 12, 14, are joined using a suitable conductor such as solder, or a conductive filament tape, conductive epoxy or other curable adhesive, metal, flexible tape, or similar rigid or flexible conductor, to form a permanent electrical coupling 22.

Preferably, adjacent packaged devices are operably coupled using numerous lateral contacts in the manner shown and described the example of FIG. 1, forming an assembly or subassembly wherein the devices are configured for operation in concert as part of a multi-package system 10. It should be appreciated by those skilled in the arts that one or more additional devices (not shown) may also be included either laterally, that is, coplanarly, or vertically in a package-on-package configuration, in various combinations within the scope of the invention. It may be seen in FIG. 1 that the devices 12, 14, may also be provided with vertical connections 24, such as solder balls joined to corresponding bond pads on a substrate 16, as is common in the arts. It should be noted that the use of lateral connections 20 preferably provides a region 26 of the substrate 16 where internal traces (18) may be intentionally absented, thus simplifying the layout or making area available for other use.

An alternative implementation of the lateral contacts 21 and their coupling 23 is shown in the close-up view of FIG. 3, illustrating that alternative lateral contact 21 configurations and connection 23 locations are possible without departure from the principles of the invention. As in the example of FIGS. 1 and 2, the first device 13, and the second device 15, each have at least one lateral electrical contact 21 suitable for completing an operable electrical connection. In this instance, the lateral electrical contacts 21 are routed directly to the edges of their respective devices 13, 15, without contacting their package substrates 17, 19. Preferably, the lateral contacts 21 of the two similarly configured coplanar devices, 13, 15, are joined using solder or other conductive material to form a permanent electrical coupling 23 as in the previous example.

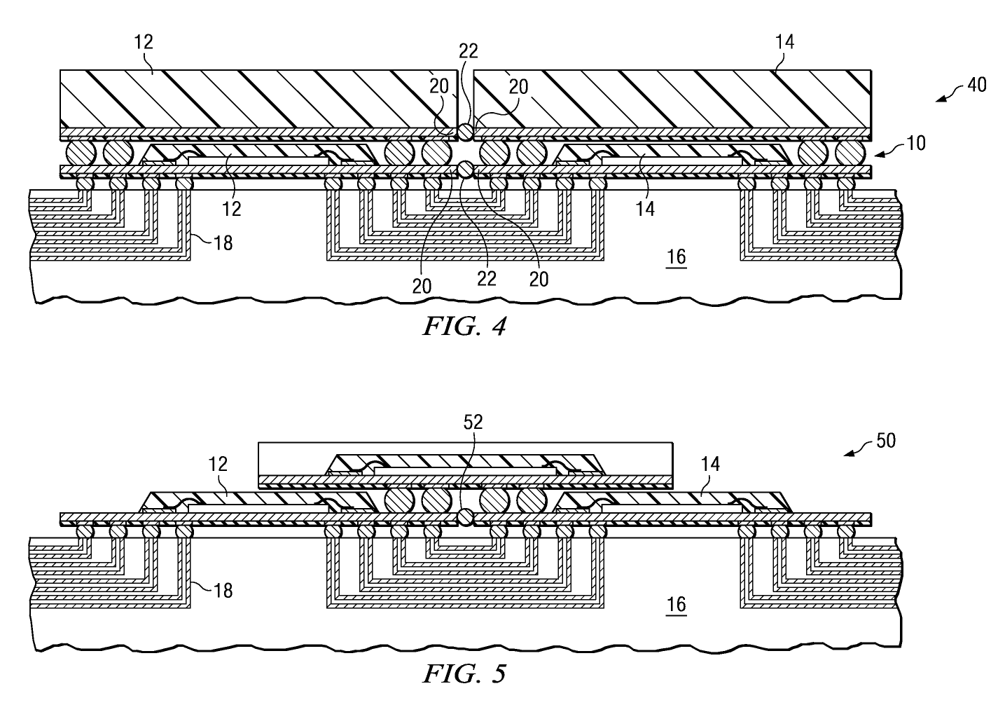

FIG. 4 is a cutaway side view illustrating an example of a PoP assembly 40 implementing a preferred embodiment of the invention. As shown, two multiple package semiconductor device systems 10 configured in the manner described with respect to FIG. 1 each include coplanar devices 12, 14. Accordingly, electrical connections 22 couple lateral electrical contacts 20 between adjacent devices, 12, 14. As can be seen in FIG. 4, the invention is not limited to one particular level of coplanar devices. For example, the coplanar devices may be at the board level, on stack levels above board level, or both. An additional dimension may be obtained by implementing embodiments of the invention in successive stack levels 10 of a PoP package system 40.

Another example of a PoP assembly 50 implementing a preferred embodiment of the invention is depicted in a cutaway side view in FIG. 5. As shown, a pyramid ( in cross section) configuration may use lateral connection(s) 52 according to the invention among adjacent coplanar devices 12, 14, in the manner described herein, in combination with existing PoP landing pad configurations.

The invention provides advantages including but not limited to one or more of the following: reduction in the area required for multi-package semiconductor device assemblies, increased efficiency, higher pin count, increased data throughput, and reduced costs. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

We claim:

1. A multi-package semiconductor device system comprising:
a first packaged semiconductor device having at least one lateral electrical contact;
a second packaged semiconductor device having at least one lateral electrical contact; wherein, the first packaged semiconductor device and the second packaged semiconductor device are fixed in a coplanar configuration; and wherein,
at least one lateral electrical contact of the first packaged semiconductor device is coupled to least one lateral electrical contact of the second packaged semiconductor device for operation in concert.

2. A multi-package semiconductor device system according to claim 1 further comprising one or more additional packaged semiconductor devices, each having at least one lateral electrical contact and operably coupled to a lateral electrical contact of at least on other coplanar semiconductor device.

3. A multi-package semiconductor device system according to claim 1 further comprising a substrate having a vertical electrical interface underlying at least one of the packaged semiconductor devices.

4. A multi-package semiconductor device system according to claim 1 further comprising:
a substrate having a vertical electrical interface underlying at least one of the packaged semiconductor devices; and
at least one packaged semiconductor device operably coupled to at least one additional packaged semiconductor device using a plurality of vertical connections, thereby forming a package-on-package system.

5. A multi-package semiconductor device system according to claim 1 wherein a lateral electrical contact further comprises metal.

6. A multi-package semiconductor device system according to claim 1 wherein a lateral electrical contact further comprises solder.

7. A multi-package semiconductor device system according to claim 1 wherein a lateral electrical contact further comprises flexible tape.

8. A multi-package semiconductor device system according to claim 1 wherein a lateral electrical contact further comprises filament tape.

9. A method for manufacturing a multi-package semiconductor assembly comprising the steps of:
providing a plurality of packaged semiconductor devices, each of the semiconductor devices having at least one electrical contact adapted for lateral coupling;
using the electrical contacts adapted for lateral coupling, operably coupling at least two of the packaged semiconductor devices, thereby forming a multi-package laterally interconnected semiconductor assembly suitable for operation in concert.

10. A method for manufacturing a multi-package semiconductor assembly according to claim 9 further comprising the steps of:
providing a substrate configured for receiving a multi-package laterally interconnected semiconductor assembly: and
operably connecting a multi-package laterally interconnected semiconductor assembly to the substrate.

11. A method for manufacturing a multi-package semiconductor assembly according to claim 9 further comprising the steps of:
providing a PCB configured for receiving a multi-package laterally interconnected semiconductor assembly: and
operably connecting a multi-package laterally interconnected semiconductor assembly to the PCB.

12. A method for manufacturing a multi-package semiconductor assembly according to claim 9 further comprising the steps of:
providing a PWB configured for receiving a multi-package laterally interconnected semiconductor assembly: and
operably connecting a multi-package laterally interconnected semiconductor assembly to the PWB.

13. A method for manufacturing a multi-package semiconductor assembly according to claim 9 further comprising the steps of:
providing a semiconductor device configured for receiving a multi-package laterally interconnected semiconductor assembly: and
operably connecting a multi-package laterally interconnected semiconductor assembly to the semiconductor device.

14. A method for manufacturing a multi-package semiconductor assembly according to claim 9 further comprising the steps of:
providing a multi-package laterally interconnected semiconductor assembly having a surface configured for receiving a multi-package laterally interconnected semiconductor assembly: and
operably connecting a multi-package laterally interconnected semiconductor assembly to the surface.

15. A method for manufacturing a multi-package semiconductor assembly according to claim 9 wherein the step of operably coupling at least two of the packaged semiconductor devices further comprises forming a metal bond between adjacent lateral electrical contacts.

16. A method for manufacturing a multi-package semiconductor assembly according to claim 9 wherein the step of operably coupling at least two of the packaged semiconductor devices further comprises soldering adjacent lateral electrical contacts.

17. A method for manufacturing a multi-package semiconductor assembly according to claim 9 wherein the step of operably coupling at least two of the packaged semiconductor devices further comprises taping adjacent lateral electrical contacts.

18. A method for manufacturing a multi-package semiconductor assembly according to claim 9 wherein the step of operably coupling at least two of the packaged semiconductor devices further comprises securing adjacent lateral electrical contacts using a curable adhesive.
